(19) United States
(12) Patent Application Publication
(10) Pub. No.: US 2026/0229385 A1
(43) Pub. Date: Aug. 6, 2026

(54) WIRING HARNESS

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Naoya HAMAMOTO, Mie (JP); Ryo KUROISHI, Mie (JP); Yuichi KIMOTO, Mie (JP)

(21) Appl. No.: 19/147,715

(22) PCT Filed: Jan. 11, 2024
(86) PCT No.: PCT/JP2024/000375

§ 371 Date: Jul. 14, 2025

(30) Foreign Application Priority Data
Jan. 26, 2023 (JP) 2023-010203

(51) Int. Cl. H01B 7/18; H01B 7/00

(52) U.S. Cl. CPC H01B 7/1805; H01B 7/0045

(57) ABSTRACT

A wiring harness includes a plurality of shielded wires (13, 14) each including a core wire (13a, 14a) and an electromagnetic shield member (13c, 14c) covering an outer periphery of the core wire, a connecting portion formed by connecting the core wires to each other, a resin case (21) for covering an outer periphery of the connecting portion, a shield coupling member (31) to be connected to a plurality of the electromagnetic shield members while covering an outer periphery of the resin case, and a binding band (33) for collectively binding and connecting the respective electromagnetic shield members of the plurality of shielded wires and the shield coupling member while binding the plurality of shielded wires. The resin case includes a spacer portion (24) for suppressing deformation of the plurality of shielded wires by being interposed between the plurality of shielded wires inside the binding band.

### TECHNICAL FIELD

The present disclosure relates to a wiring harness.

### BACKGROUND

Conventionally, some wiring harnesses include a connecting portion formed by connecting core wires of a plurality of wires to each other (see, for example, Patent Document 1). In this wiring harness, the connecting portion is exposed from an insulation coating of each wire, but an exposed part including the connecting portion is prevented from being wetted from outside by being covered by a water stop member.

### PRIOR ART DOCUMENT

### Patent Document

Patent Document 1: JP 2012-248527 A

### SUMMARY OF THE INVENTION

### Problems to be Solved

Shielded wires may be adopted as the wires of the wiring harness as described above. Since the shielded wire includes an electromagnetic shield member such as a braided wire for covering the outer periphery of a core wire via an insulation coating, the emission of electromagnetic waves is suppressed. However, even if the shielded wires are adopted, electromagnetic waves may be emitted from the periphery of the connecting portion due to the exposure of the periphery of the connecting portion from the electromagnetic shield members. As a countermeasure against that, it is thought to directly connect the electromagnetic shield members outside the connecting portion, but it has been difficult to satisfactorily connect the electromagnetic shield members while covering the entire periphery of the connecting portion.

The present disclosure aims to provide a wiring harness capable of suppressing the emission of electromagnetic waves from the periphery of a connecting portion by ensuring a good connected state of electromagnetic shield members.

### Means to Solve the Problem

The present disclosure is directed to a wiring harness with a plurality of shielded wires each including a core wire and an electromagnetic shield member covering an outer periphery of the core wire, a connecting portion formed by connecting the core wires to each other, a resin case for covering an outer periphery of the connecting portion, a shield coupling member to be connected to a plurality of the electromagnetic shield members while covering an outer periphery of the resin case, and a binding band for collectively binding and connecting the respective electromagnetic shield members of the plurality of shielded wires and the shield coupling member while binding the plurality of shielded wires, the resin case including a spacer portion for suppressing deformation of the plurality of shielded wires by being interposed between the plurality of shielded wires inside the binding band.

### Effect of the Invention

According to the wiring harness of the present disclosure, it is possible to suppress the emission of electromagnetic waves from the periphery of the connecting portion by ensuring a good connected state of the electromagnetic shield members.

### BRIEF DESCRIPTION OF THE DRAWINGS

FIG. 1 is a section of a wiring harness in a first embodiment.

FIG. 2 is a partial enlarged section of the wiring harness in the first embodiment.

FIG. 3 is a partial enlarged section of the wiring harness in the first embodiment.

FIG. 4 is an exploded perspective view of a part of the wiring harness in the first embodiment.

FIG. 5 is an exploded perspective view of a resin case in the first embodiment.

FIG. 6 is a perspective view of a part of the wiring harness in the first embodiment.

FIG. 7 is a transverse section of a part of the wiring harness in the first embodiment.

FIG. 8 is a section of a wiring harness in a second embodiment.

FIG. 9 is a partial enlarged section of the wiring harness in the second embodiment.

FIG. 10 is a partial enlarged section of the wiring harness in the second embodiment.

FIG. 11 is an exploded perspective view of a part of the wiring harness in the second embodiment.

FIG. 12 is an exploded perspective view of a resin case in the second embodiment.

FIG. 13 is a perspective view of a part of the wiring harness in the second embodiment.

FIG. 14 is a transverse section of a part of the wiring harness in the second embodiment.

FIG. 15 is a section of a wiring harness in another example.

FIG. 16 is a partial enlarged section of the wiring harness in the other example.

### DETAILED DESCRIPTION TO EXECUTE THE INVENTION

### Description of Embodiments of Present Disclosure

First, embodiments of the present disclosure are listed and described.

[1] The wiring harness of the present disclosure is provided with a plurality of shielded wires each including a core wire and an electromagnetic shield member covering an outer periphery of the core wire, a connecting portion formed by connecting the core wires to each other, a resin case for covering an outer periphery of the connecting portion, a shield coupling member to be connected to a plurality of the electromagnetic shield members while covering an outer periphery of the resin case, and a binding band for collectively binding and connecting the respective electromagnetic shield members of the plurality of shielded wires and the shield coupling member while binding the plurality of shielded wires, the resin case including a spacer portion for suppressing deformation of the plurality of shielded wires by being interposed between the plurality of shielded wires inside the binding band.

According to this configuration, the emission of electromagnetic waves from the periphery of the connecting portion is suppressed by being covered by the shield coupling member. Further, since the plurality of electromagnetic shield members are collectively connected to the shield coupling member by the binding band, the number of components can be reduced, for example, as compared to a configuration in which the plurality of electromagnetic shield members are respectively connected to the shield coupling member by a plurality of binding bands or the like. Since the deformation of the plurality of shielded wires bound by the binding band is suppressed by the spacer portion interposed between the plurality of shielded wires, the plurality of electromagnetic shield members and the shield coupling member can be satisfactorily connected. For example, in a configuration not including the spacer portion, the plurality of shielded wires are deformed, such as by being deflected toward each other when being bound by the binding band, whereby connection may become unstable, such as due to a reduction in surface pressure between the electromagnetic shield members and the shield coupling member. In contrast, since the deformation of the plurality of shielded wires is suppressed by the spacer portion, the plurality of electromagnetic shield members and the shield coupling member can be satisfactorily connected. Further, since the spacer portion is provided in the resin case, the number of components can be reduced, for example, as compared to the case where the spacer portion is provided separately from the resin case.

[2] In [1] described above, the spacer portion may include arcuate portions along outer peripheries of the shielded wires.

According to this configuration, since the spacer portion includes the arcuate portions along the outer peripheries of the shielded wires, the squeezing deformation of the shielded wires can be satisfactorily suppressed.

[3] In [1] or [2] described above, the shielded wire may include an outer insulation coating covering an outer periphery of the electromagnetic shield member, the electromagnetic shield member may include a folded portion folded from inside to outside of the outer insulation coating and arranged to cover an outer periphery of the outer insulation coating, and the binding band may collectively bind the folded portions and the shield coupling member.

According to this configuration, the folded portions of the electromagnetic shield members arranged to cover the outer peripheries of the outer insulation coatings are collectively bound with the shield coupling member by the binding band. Thus, the electromagnetic shield members can be brought into contact with the shield coupling member in wider areas, for example, as compared to the case where the electromagnetic shield members are not folded to cover the outer peripheries of the outer insulation coatings.

[4] In [3] described above, an underlay ring may be provided which is arranged between the outer insulation coating and the folded portion.

According to this configuration, the folded portions and the shield coupling member can be stably sandwiched and satisfactorily connected by the underlay rings and the binding band.

[5] In [3] described above, the folded portions may be bound by the binding band while being held in contact with outer peripheral surfaces of the outer insulation coatings.

According to this configuration, the number of components can be reduced, for example, as compared to a configuration provided with underlay rings inside the folded portions.

[6] In any one of [1] to [5] described above, the resin case may include a band restricting portion engageable with the binding band to restrict a deviation of the binding band along a longitudinal direction of the shielded wires.

According to this configuration, since the deviation of the binding band along the longitudinal direction of the shielded wires is restricted by the band restricting portion, a connected state of the plurality of electromagnetic shield members and the shield coupling member can be stably maintained.

[7] In any one of [1] to [6] described above, the resin case may include a first divided case and a second divided case to be assembled to sandwich the connecting portion.

According to this configuration, the outer periphery of the connecting portion can be easily covered by the first and second divided cases.

[8] In [7] described above, the first and second divided cases may have the same shape.

According to this configuration, since one type of a mold for manufacturing the first and second divided cases is necessary, manufacturing is facilitated. Further, parts management of the first and second divided cases is facilitated.

[9] In [7] or [8] described above, the first and second divided cases may include locking portions to be locked to each other on both sides in a width direction, the width direction being an arrangement direction of the plurality of shielded wires to be bound by the binding band.

According to this configuration, the both sides in the width direction of the resin case can be locked in a well-balanced manner by the locking portions.

[10] In any one of [7] to [9] described above, the first and second divided cases may include intermediate locking portions to be locked to each other between the plurality of shielded wires to be bound by the binding band.

According to this configuration, a space between the plurality of shielded wires to be bound by the binding band can be effectively utilized by the intermediate locking portions.

[11] In any one of [1] to [10] described above, the plurality of shielded wires may include a first shielded wire and a second shielded wire extending in directions opposite to each other with the connecting portion as a base point, and at least a plurality of the first shielded wires or a plurality of the second shielded wires may be provided and bound by the binding band.

According to this configuration, in the case of binding the plurality of shielded wires, the plurality of electromagnetic shield members and the shield coupling member can be satisfactorily connected while the number of components is reduced.

[12] In any one of [1] to [11] described above, a waterproof member may be provided which collectively covers the resin case, the electromagnetic shield members, the shield coupling member and the binding band.

According to this configuration, the connecting portion, the electromagnetic shield members and the shield coupling member can be collectively prevented from being wetted.

[13] In any one of [1] to [11] described above, a connecting portion waterproof member may be provided which covers the connecting portion in the resin case, and the shield coupling member and the binding band may be exposed.

According to this configuration, the connecting portion can be prevented from being wetted by the connecting portion waterproof member. Further, a size reduction can be, for example, achieved as compared to a configuration provided with a waterproof member for collectively covering the shield coupling member and the like.

### Details of Embodiments of Present Disclosure

### First Embodiment

A specific example of a wiring harness of the present disclosure is described below with reference to the drawings. For the convenience of description, some components may be shown in an exaggerated or simplified manner in each drawing. Further, a dimension ratio of each part may be different in each drawing. “Parallel”, “orthogonal” and “true circular” in this specification mean not only strictly parallel, orthogonal and true circular, but also substantially orthogonal, parallel and true circular within a range in which functions and effects in embodiments are achieved. Note that the present invention is not limited to these illustrations, but is represented by claims and intended to include all changes in the scope of claims and in the meaning and scope of equivalents.

### Configuration of Wiring Harness 11

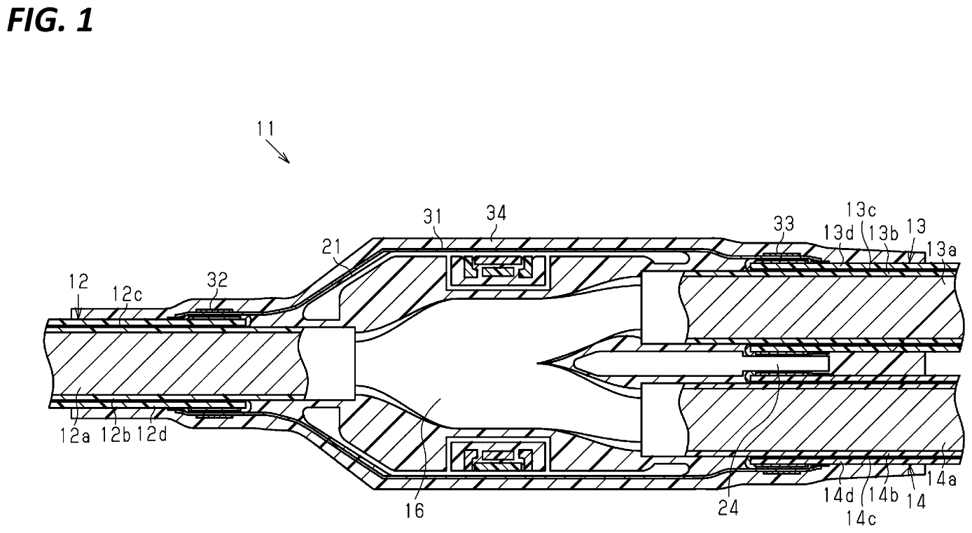

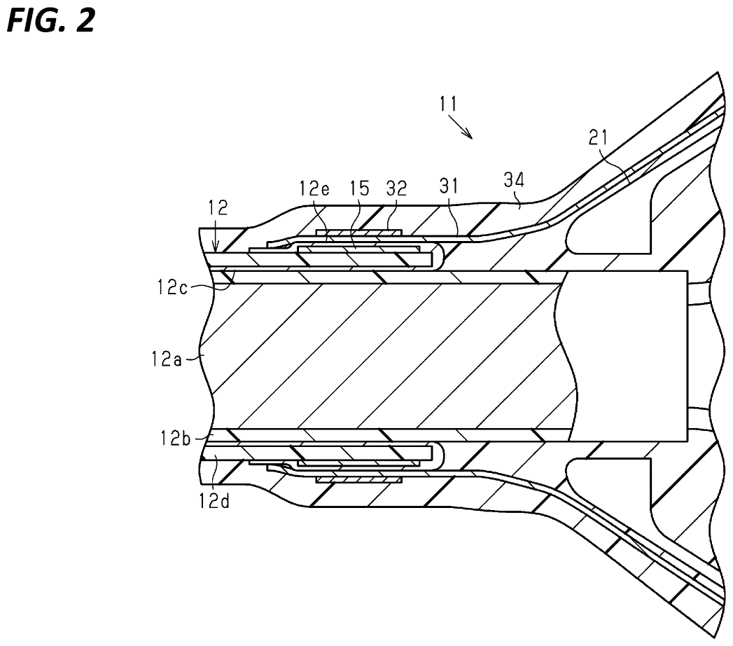

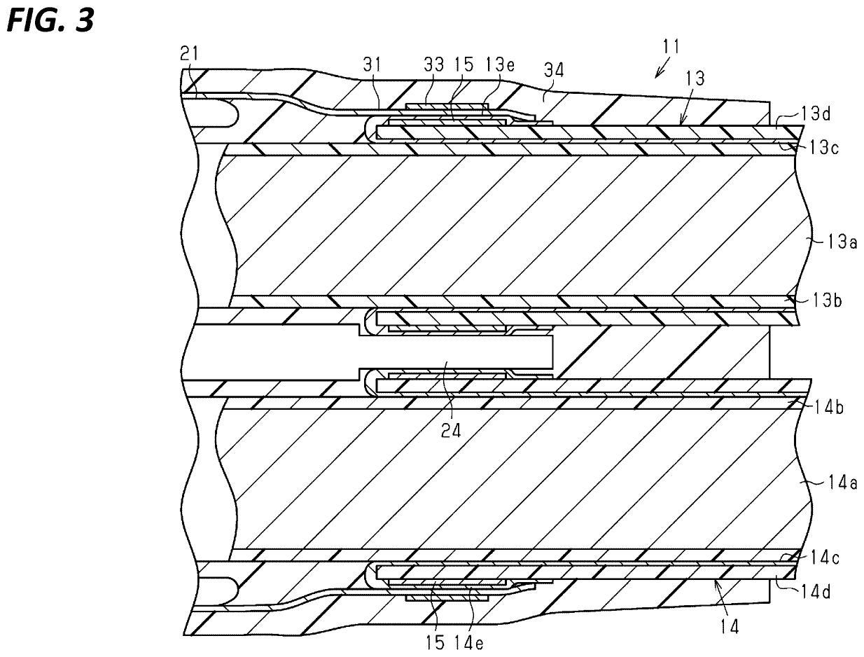

As shown in FIG. 1, a wiring harness 11 is provided with one first shielded wire 12 serving as a shielded wire, two second shielded wires 13, 14 serving as shielded wires and underlay rings 15 (see FIGS. 2 and 3). Further, the wiring harness 11 is provided with a resin case 21, a shield coupling member 31, a crimp ring 32 (see FIG. 2), a binding crimp ring 33 serving as a binding band (see FIG. 3) and a waterproof member 34.

### Configurations of First Shielded Wire 12, Second Shielded Wires 13, 14 and Underlay Rings 15

As shown in FIG. 2, the first shielded wire 12 includes a first core wire 12 serving as a core wire and an inner insulation coating 12b covering the outer periphery of the first core wire 12a. The first core wire 12a has a circular transverse cross-sectional shape. Further, the first shielded wire 12 includes a first electromagnetic shield member 12c serving as an electromagnetic shield member covering the outer periphery of the inner insulation coating 12b and an outer insulation coating 12d covering the outer periphery of the first electromagnetic shield member 12c.

As shown in FIG. 3, the second shielded wire 13, 14 includes a second core wire 13a, 14a serving as a core wire and an inner insulation coating 13b, 14b covering the outer periphery of the second core wire 13a, 14a. The second core wire 13a, 14a has a circular transverse cross-sectional shape. Further, the second core wire 13, 14 includes a second electromagnetic shield member 13c, 14c serving as an electromagnetic shield member covering the outer periphery of the inner insulation coating 13b, 14b and an outer insulation coating 13d, 14d covering the outer periphery of the second electromagnetic shield member 13c, 14c.

The first electromagnetic shield member 12c and the second electromagnetic shield members 13c, 14c are for suppressing the emission of electromagnetic waves from the first core wire 12a and the second core wires 13a, 14a. The first electromagnetic shield member 12c and the second electromagnetic shield members 13c, 14c of this embodiment are, for example, braided wires each formed by braiding electrically conductive strands of aluminum alloy or the like into a tubular shape. Note that the shapes, external appearances and the like of the braided wires in the first electromagnetic shield member 12c and the second electromagnetic shield members 13c, 14c are schematically shown as appropriate in figures.

The first core wire 12a and the second core wires 13a, 14a are provided to be exposed to outside in end parts of the first electromagnetic shield member 12c and the second electromagnetic shield members 13c, 14c. Further, the first electromagnetic shield member 12c and the second electromagnetic shield members 13c, 14c are provided to be exposed to outside in end parts of the first shielded wire 12 and the second shielded wires 13, 14. Each of the first electromagnetic shield member 12c and the second electromagnetic shield members 13c, 14 includes a folded portion 12e, 13e, 14e folded from inside to outside of the outer insulation coating 12d, 13d, 14d and arranged to cover the outer periphery of the outer insulation coating 12d, 13d, 14d. For example, each of the first electromagnetic shield member 12c and the second electromagnetic shield members 13c, 14 includes the folded portion 12e, 13e, 14e formed by folding a part exposed to the outside of the outer insulation coating 12d, 13d, 14d.

The outer insulation coatings 12d, 13d and 14d are first stripped in the end parts of the first shielded wire 12 and the second shielded wires 13, 14. Subsequently, the first electromagnetic shield member 12c and the second electromagnetic shield members 13c, 14c are folded in the end parts of the first shielded wire 12 and the second shielded wires 13, 14, and then the inner insulation coatings 12b, 13b and 14b are stripped. In this way, the first electromagnetic shield member 12c and the second electromagnetic shield members 13c, 14c are exposed, the folded portions 12e, 13e, 14e are formed and, further, the first core wire 12a and the second core wires 13a, 14a are exposed.

The underlay ring 15 is made of metal and formed into a tubular shape. The underlay ring 15 is arranged between the outer insulation coating 12d, 13d, 14d and the folded portion 12e, 13e, 14e. That is, the underlay rings 15 are arranged on the outer peripheries of the outer insulation coatings 12d, 13d and 14d when the first electromagnetic shield member 12c and the second electromagnetic shield members 13c, 14c are folded.

The first core wire 12a and the second core wires 13a, 14 are connected to configure a connecting portion 16. In this embodiment, the first core wire 12a and the second core wires 13a, 14 are directly welded. The first shielded wire 12 and the second shielded wires 13, 14 extend in directions opposite to each other with the connecting portion 16 as a base point. In particular, one first shielded wire 12 extends in one direction (leftward direction in FIG. 1) and two second shielded wires 13, 14 extend in the other direction (rightward direction in FIG. 1) with the connecting portion 16 as a base point. For example, the wiring harness 11 electrically connects a battery connected to the first core wire 12a and an electrical device connected to each of the second core wires 13a, 14a.

### Configuration of Resin Case 21

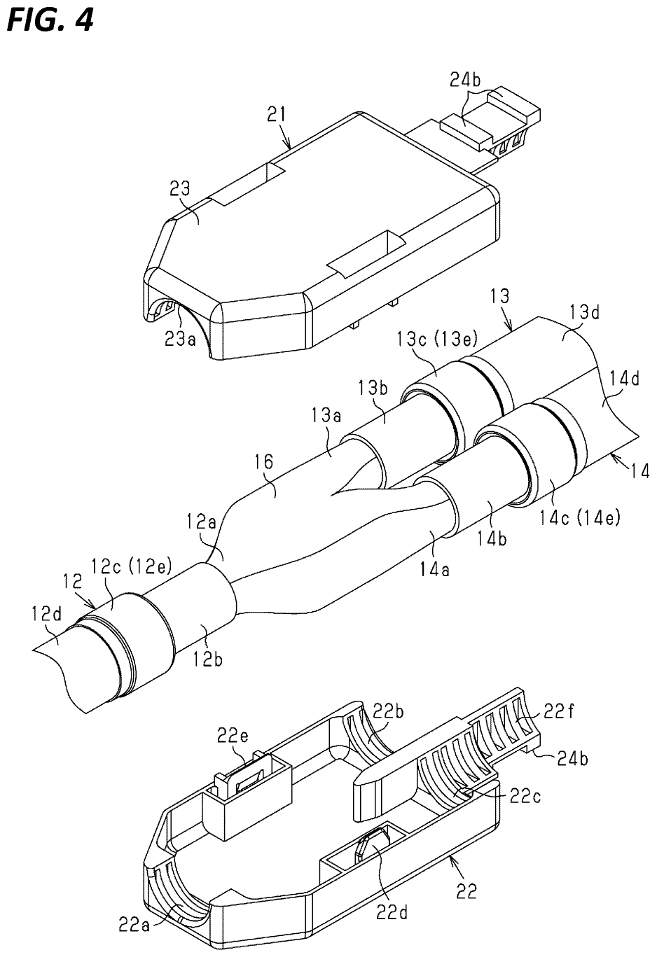

Further, as shown in FIG. 4, the resin case 21 is formed into a flat box shape capable of covering the outer periphery of the connecting portion 16. The resin case 21 is composed of a first divided case 22 and a second divided case 23 to be assembled to sandwich the connecting portion 16. A synthetic resin such as polypropylene, polyamide or polyacetal can be, for example, used as a material of the resin case 21, i.e. the first and second divided cases 22, 23. The first and second divided cases 22, 23 have the same shape and size. For example, the first and second divided cases 22, 23 may be interchangeable and/or may be manageable by the same parts management number.

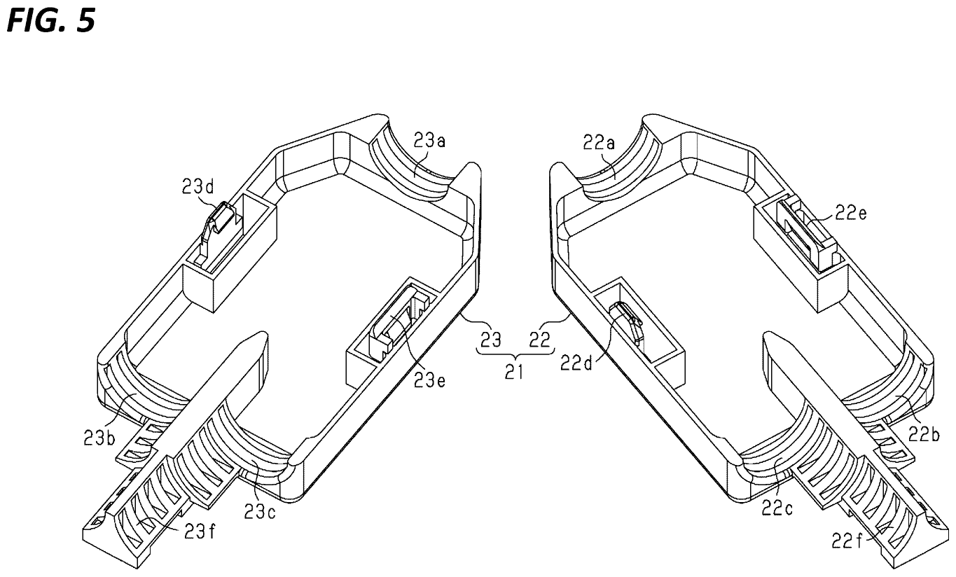

As shown in FIGS. 4 and 5, the first and second divided cases 22, 23 include semicircular openings 22a, 22b, 22c, 23a, 23b and 23c having a semicircular shape and arranged at positions to sandwich the respective exposed inner insulation coatings 12b, 13b and 14b. Further, the first and second divided cases 22, 23 include locking portions 22d, 22e, 23d, 23e to be locked to each other on both sides in a width direction, which is an arrangement direction of the second shielded wires 13, 14. Note that, in the first divided case 22, one locking portion 22d is a male locking portion, and the other locking portion 22e is a female locking portion. Further, in the second divided case 23, one locking portion 23d is a male locking portion, and the other locking portion 23e is a female locking portion. The first and second divided cases 22, 23 are locked to each other by fitting the male locking portion of the first divided case 22 into the female locking portion of the second divided case 23 and fitting the male locking portion of the second divided case 23 into the female locking portion of the first divided case 22.

### Configurations of Shield Coupling Member 31, Crimp Ring 32 and Binding Crimp Ring 33

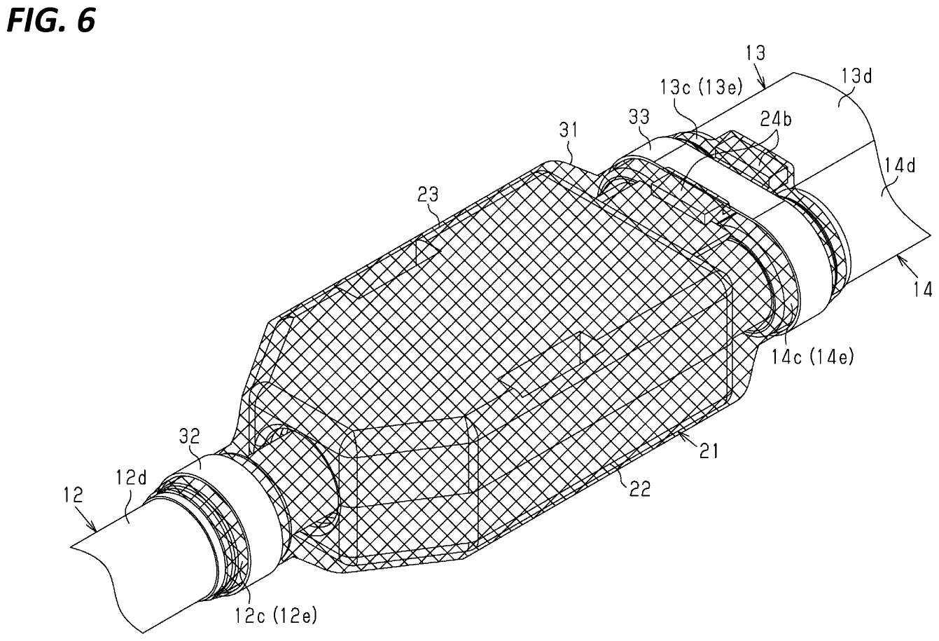

As shown in FIG. 6, the shield coupling member 31 is for suppressing the emission of electromagnetic waves from the resin case 21. The shield coupling member 31 is connected to the first electromagnetic shield member 12c and the second electromagnetic shield members 13c, 14c while covering the outer periphery of the resin case 21. The shield coupling member 31 is flexible. The shield coupling member 31 of this embodiment is, for example, a braided wire formed by braiding electrically conductive strands of aluminum alloy or the like into a tubular shape. Note that the shape, external appearance and the like of the braided wire in the shield coupling member 31 are schematically shown as appropriate in the figures. The shield coupling member 31 is arranged to continuously cover a range from the folded portion 12e of the first electromagnetic shield member 12c to the folded portions 13e, 14e of the second electromagnetic shield members 13c, 14c.

As shown in FIG. 2, the crimp ring 32 is made of metal and formed into a tubular shape. The crimp ring 32 connects the folded portion 12e of the first electromagnetic shield member 12c and the shield coupling member 31. In particular, the crimp ring 32 is crimped from an outer peripheral side to connect the folded portion 12e of the first electromagnetic shield member 12c and the shield coupling member 31 by fastening these from the outer peripheral side. The folded portion 12e and the shield coupling member 31 are sandwiched and connected by the underlay ring 15 and the crimp ring 32.

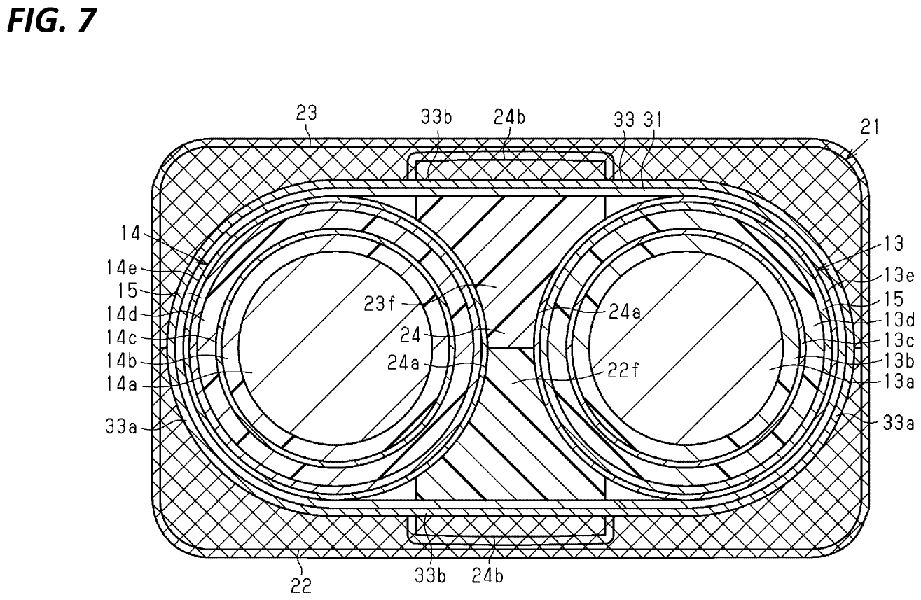

As shown in FIGS. 3 and 7, the binding crimp ring 33 is made of metal and formed into a tubular shape. The binding crimp ring 33 connects the folded portions 13e, 14e of the second electromagnetic shield members 13c, 14c and the shield coupling member 31. In particular, the binding crimp ring 33 is crimped from an outer peripheral side, whereby the folded portions 13e, 14e of the two second electromagnetic shield members 13c, 14c and the shield coupling member 31 are connected by being collectively bound while the two second shielded wires 13, 14 are bound. Note that the binding crimp ring 33 includes a pair of semicircular portions 33a provided on both sides in the width direction of the resin case 21 and a pair of coupling portions 33b linking end parts of the semicircular portions 33a when viewed from a longitudinal direction of the second shielded wires 13, 14 (see FIG. 7) in an assembled state.

### Configuration of Waterproof Member 34

As shown in FIG. 1, the waterproof member 34 collectively covers the resin case 21, the folded portions 12e, 13e and 14e of the first electromagnetic shield member 12c and the second electromagnetic shield members 13c, 14c, the shield coupling member 31, the crimp ring 32, the binding crimp ring 33 and the like. The waterproof member 34 of this embodiment is an electrically non-conductive mold resin. The waterproof member 34 of this embodiment is molded by filling a resin material in a molten state in a range surrounded by an unillustrated mold arranged outside the shield coupling member 31 and the like. Note that, in this embodiment, the resin material in the molten state is cured after entering to reach the connecting portion 16 and the like arranged inside the resin case 21. For example, the waterproof member 34 of this embodiment is also arranged inside the resin case 21.

### Partial Detailed Configuration of Resin Case 21

As shown in FIGS. 3 and 7, the resin case 21 includes a spacer portion 24. The spacer portion 24 suppresses the deformation of the second shielded wires 13, 14 by being interposed between the two second shielded wires 13, 14 inside the binding crimp ring 33.

In particular, as shown in FIG. 7, the spacer portion 24 is composed of a first divided spacer portion 22f provided in the first divided case 22 and a second divided spacer portion 23f provided in the second divided case 23.

The spacer portion 24 includes arcuate portions 24a along the outer peripheries of the second shielded wires 13, 14. In particular, the arcuate portion 24a is formed into an arcuate shape along the outer periphery of the folded portion 13e, 14e. A pair of the arcuate portions 24a are formed to substantially entirely fill up a gap between the facing folded portions 13e, 14e when viewed from the longitudinal direction of the second shielded wires 13, 14.

As shown in FIGS. 6 and 7, the resin case 21 includes band restricting portions 24b engageable with the binding crimp ring 33 to restrict a deviation of the binding crimp ring 33 along the longitudinal direction of the second shielded wires 13, 14. The band restricting portions 24b project from the spacer portion 24. A pair of the band restricting portions 24b are provided in the longitudinal direction of the second shielded wires 13, 14 and the binding crimp ring 33 is arranged between the pair of band restricting portions 24b, thereby restricting the deviation of the binding crimp ring 33 along the longitudinal direction of the second shielded wires 13, 14. Further, the band restricting portions 24b are provided in each of the first and second divided cases 22, 23. For example, the band restricting portions 24b are provided on front and back sides of the resin case 21.

Next, functions of the wiring harness 11 configured as described above are described.

Since the first shielded wire 12 includes the first electromagnetic shield member 12c covering the outer periphery of the first core wire 12a via the inner insulation coating 12b, the emission of electromagnetic waves from the first shielded wire 12 is suppressed. Further, since the second shielded wires 13, 14 include the second electromagnetic shield members 13c, 14c covering the outer peripheries of the second core wires 13a, 14a via the inner insulation coatings 13b, 14b, the emission of electromagnetic waves from the second shielded wires 13, 14 is suppressed. Further, since the connecting portion 16 is covered by the shield coupling member 31 connected to the first electromagnetic shield member 12c and the second electromagnetic shield members 13c, 14c via the resin case 21, the emission of electromagnetic waves from the periphery of the connecting portion 16 is suppressed.

Next, effects of the first embodiment are described below.

(1) The two second electromagnetic shield members 13c, 14c are collectively connected to the shield coupling member 31 by the binding crimp ring 33. Thus, the number of components can be reduced, for example, as compared to a configuration in which the two second electromagnetic shield members 13c, 14c are respectively connected to the shield coupling member 31 by a plurality of crimp rings or the like. The deformation of the two second shielded wires 13, 14 bound by the binding crimp ring 33 is suppressed by the spacer portion 24 interposed between the two second shielded wires 13 and 14. Thus, the two second electromagnetic shield members 13c, 14c and the shield coupling member 31 can be satisfactorily connected. For example, in a configuration not including the spacer portion 24, the two second shielded wires 13, 14 are deformed, such as by being deflected toward each other, whereby connection may become unstable, such as due to a reduction in surface pressure between the second electromagnetic shield members 13c, 14c and the shield coupling member 31. In contrast, since the deformation of the two second shielded wires 13, 14 is suppressed by the spacer portion 24, the two second electromagnetic shield members 13c, 14c and the shield coupling member 31 can be satisfactorily connected. Further, since the spacer portion 24 is provided in the resin case 21, the number of components can be reduced, for example, as compared to the case where the spacer portion 24 is provided separately from the resin case 21.

(2) Since the spacer portion 24 includes the arcuate portions 24a along the outer peripheries of the second shielded wires 13, 14, the squeezing deformation of the second shielded wires 13, 14 can be satisfactorily suppressed.

(3) The folded portions 13e, 14e of the second electromagnetic shield members 13c, 14c arranged to cover the outer peripheries of the outer insulation coatings 13d, 14d are collectively bound with the shield coupling member 31 by the binding crimp ring 33. Thus, the second electromagnetic shield members 13c, 14c can be brought into contact with the shield coupling member 31 in wider areas, for example, as compared to the case where the second electromagnetic shield members 13c, 14c are not folded to cover the outer peripheries of the outer insulation coatings 13d, 14d.

(4) The underlay rings 15 are arranged between the outer insulation coatings 13d, 14d and the folded portions 13e, 14e. Thus, the folded portions 13e, 14e and the shield coupling member 31 can be stably sandwiched and satisfactorily connected by the underlay rings 15 and the binding crimp ring 33.

(5) The resin case 21 includes the band restricting portions 24b engageable with the binding crimp ring 33 to restrict a deviation of the binding crimp ring 33 along the longitudinal direction of the second shielded wires 13, 14. Thus, the deviation of the binding crimp ring 33 along the longitudinal direction of the second shielded wires 13, 14 is restricted by the band restricting portions 24b, wherefore the connected state of the two second electromagnetic shield members 13c, 14c and the shield coupling member 31 can be stably maintained.

(6) The resin case 21 includes the first and second divided cases 22, 23 to be assembled to sandwich the connecting portion 16. Thus, the outer periphery of the connecting portion 16 can be easily covered by the first and second divided cases 22, 23.

(7) The first and second divided cases 22, 23 have the same shape and size. Thus, one type of a mold for manufacturing the first and second divided cases 22, 23 is necessary, wherefore manufacturing is facilitated. Further, the parts management of the first and second divided cases 22, 23 is facilitated.

(8) The first and second divided cases 22, 23 include the locking portions 22d, 22e, 23d and 23e to be locked to each other on the both sides in the width direction, which is the arrangement direction of the two second shielded wires 13, 14. Thus, the both sides in the width direction of the resin case 21 can be locked in a well-balanced manner by the locking portions 22d, 22e, 23d and 23e.

(9) Adaptation is possible in the wiring harness 11 provided with the first shielded wire 12 and the second shielded wires 13, 14 extending in the directions opposite to each other with the connecting portion 16 as a base point. In this embodiment, on the side where the two second shielded wires 13, 14 are arranged, the two second electromagnetic shield members 13c, 14c and the shield coupling member 31 can be satisfactorily connected while the number of components is reduced.

(10) The resin case 21, the folded portions 12e, 13e and 14e, the shield coupling member 31, the crimp ring 32 and the binding crimp ring 33 can be collectively prevented from being wetted by the waterproof member 34.

### Second Embodiment

Since the configuration of a wiring harness 41 of a second embodiment is partially different from that of the wiring harness 11 of the first embodiment, similar components are denoted by similar reference signs and not described in detail.

### Configuration of Wiring Harness 11

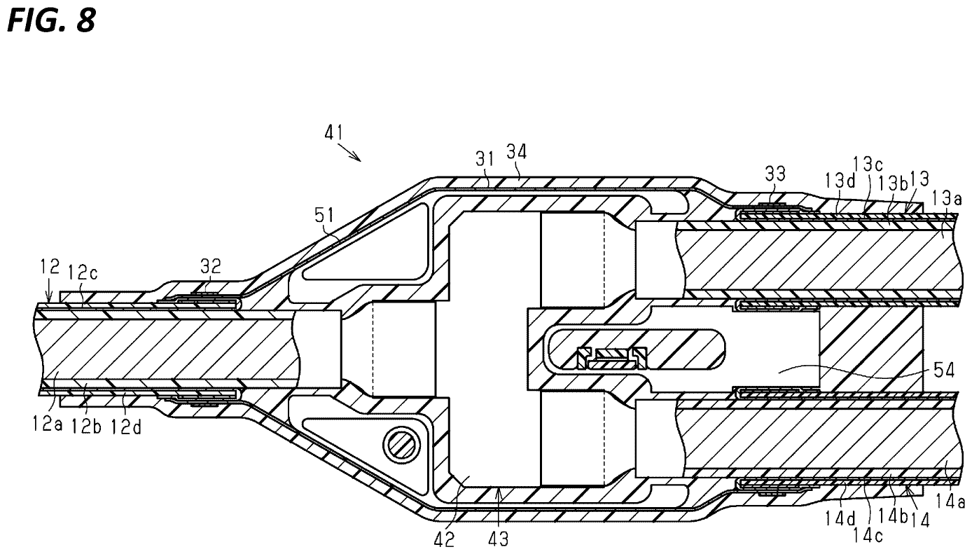

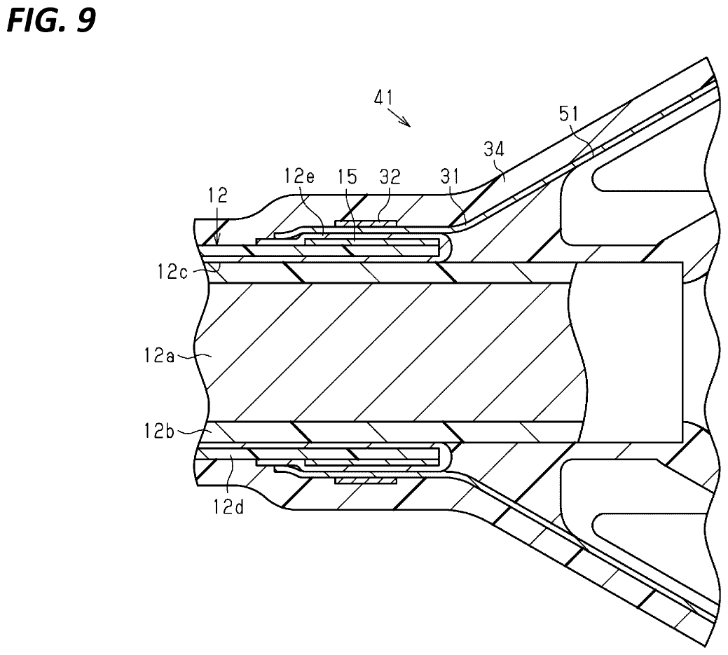

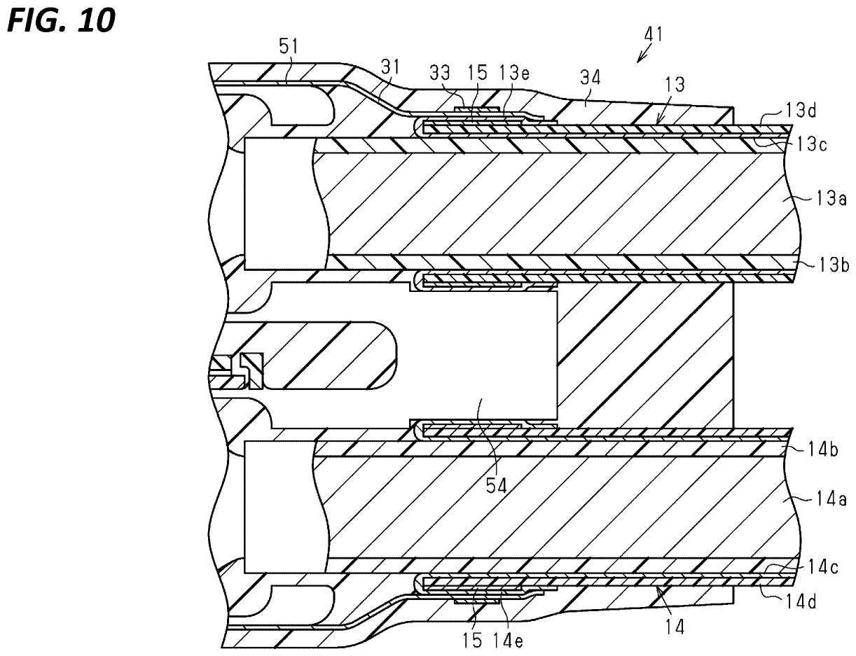

As shown in FIGS. 8 to 10, the wiring harness 41 is provided with one first shielded wire 12, two second shielded wires 13, 14, underlay rings 15 (see FIGS. 9 and 10) and a connection terminal 42. Further, the wiring harness 11 is provided with a resin case 51, a shield coupling member 31, a crimp ring 32 (see FIG. 9), a binding crimp ring 33 serving as a binding band (see FIG. 10) and a waterproof member 34.

A first core wire 12a and second core wires 13a, 14a of this embodiment are connected via the connection terminal 42. In this embodiment, a connecting portion 43 is constituted by the connection terminal 42 and the first core wire 12a and the second core wires 13a, 14a connected to the connection terminal 42. The first shielded wire 12 and the second shielded wires 13, 14 extend in directions opposite to each other with the connecting portion 43 as a base point.

### Configuration of Resin Case 51

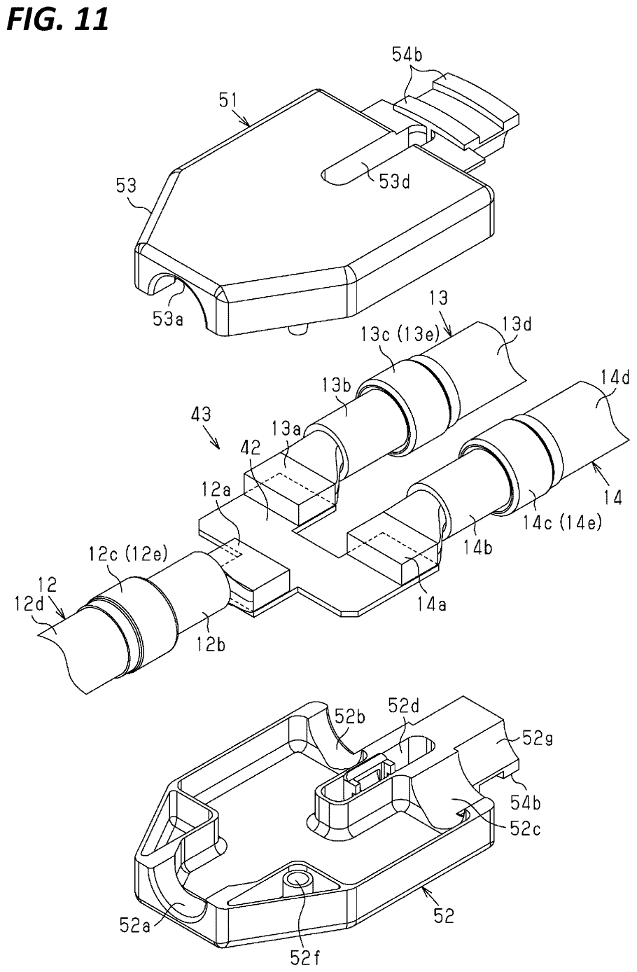

Further, as shown in FIG. 11, the resin case 51 is formed into a flat box shape capable of covering the outer periphery of the connecting portion 43. The resin case 51 is composed of a first divided case 52 and a second divided case 53 to be assembled to sandwich the connecting portion 43. A synthetic resin such as polypropylene, polyamide or polyacetal can be, for example, used as a material of the resin case 51, i.e. the first and second divided cases 52, 53.

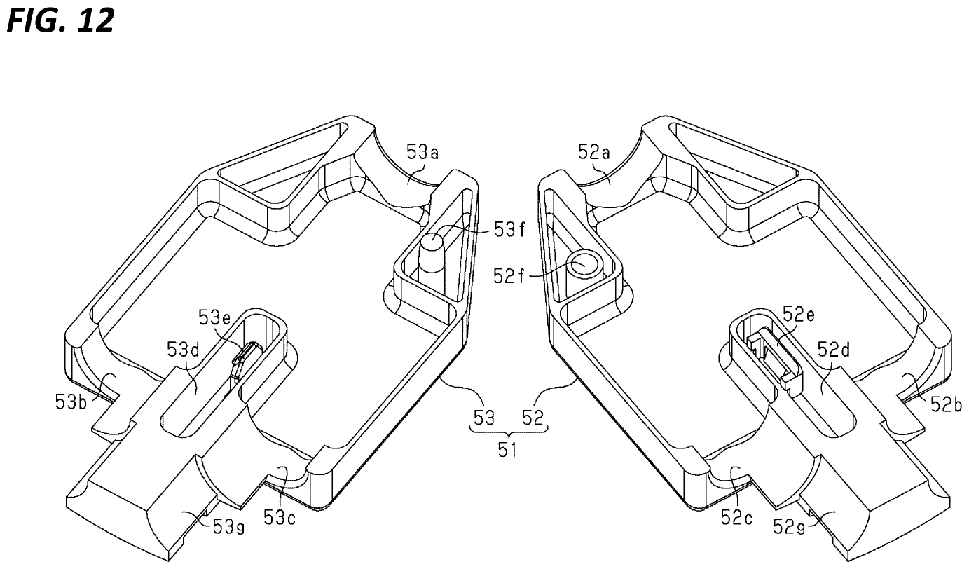

As shown in FIGS. 11 and 12, the first and second divided cases 52, 53 include semicircular openings 52a, 52b, 52c, 53a, 53b and 53c having a semicircular shape and arranged at positions to sandwich respective exposed inner insulation coatings 12b, 13b and 14b. Further, the first and second divided cases 22, 23 include through holes 52d, 53d between the two second shielded wires 13, 14 and intermediate locking portions 52e, 53e to be locked to each other on the inner walls of the through holes 52d, 53d. Note that the intermediate locking portion 52e of the first divided case 22 is a female locking portion. Further, the intermediate locking portion 53e of the second divided case 23 is a male locking portion. Further, the first divided case 52 includes a positioning recess 52f in a part of a facing surface to the second divided case 53. The second divided case 53 includes a positioning protrusion 53f in a part of a facing surface to the first divided case 52. The first and second divided cases 22, 23 are locked to each other by fitting the positioning protrusion 53f into the positioning recess 52f and the fitting the intermediate locking portions 52e, 53e thereof.

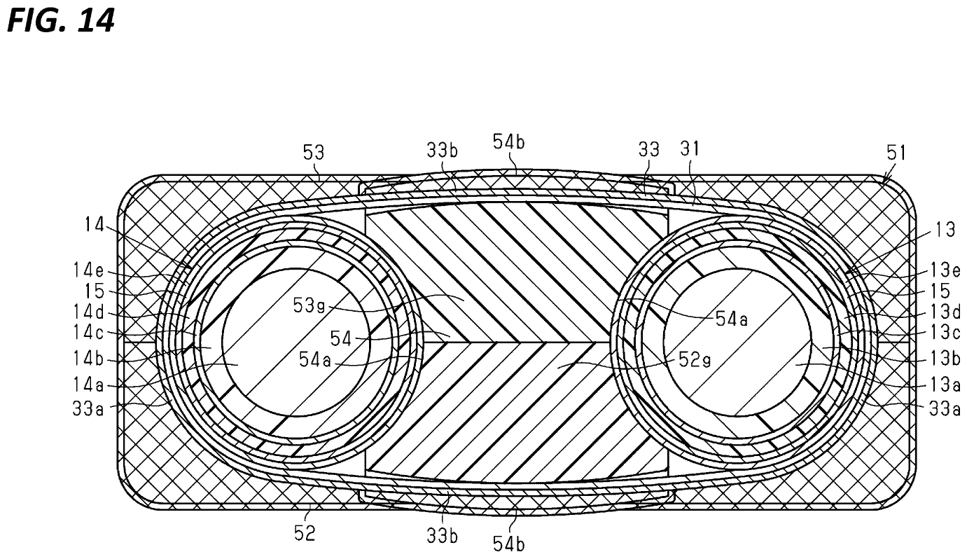

As shown in FIGS. 10 and 14, the resin case 51 includes a spacer portion 54. The spacer portion 54 suppresses the deformation of the second shielded wires 13, 14 by being interposed between the two second shielded wires 13, 14 inside the binding crimp ring 33.

In particular, as shown in FIG. 12, the spacer portion 54 is composed of a first divided spacer portion 52g provided in the first divided case 52 and a second divided spacer portion 53g provided in the second divided case 53.

As shown in FIG. 14, the spacer portion 54 includes arcuate portions 54a along the outer peripheries of the second shielded wires 13, 14. In particular, the arcuate portion 54a is formed into an arcuate shape along the outer periphery of folded portion 13e, 14e. A pair of the arcuate portions 54a are formed to substantially entirely fill up a gap between the facing folded portions 13e, 14e when viewed from the longitudinal direction of the second shielded wires 13, 14.

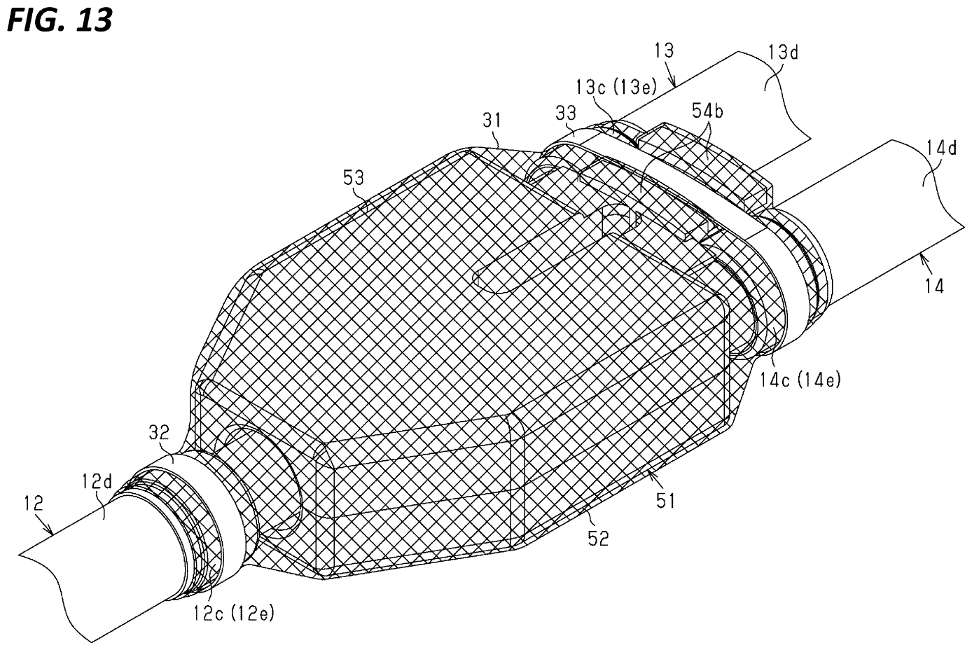

As shown in FIGS. 13 and 14, the resin case 51 includes band restricting portions 54b engageable with the binding crimp ring 33 to restrict a deviation of the binding crimp ring 33 along the longitudinal direction of the second shielded wires 13, 14. The band restricting portions 54b project from the spacer portion 54. A pair of the band restricting portions 54b are provided in the longitudinal direction of the second shielded wires 13, 14 and the binding crimp ring 33 is arranged between the pair of band restricting portions 54b, thereby restricting the deviation of the binding crimp ring 33 along the longitudinal direction of the second shielded wires 13, 14. Further, the band restricting portions 54b are provided in each of the first and second divided cases 52, 53. For example, the band restricting portions 54b are provided on front and back sides of the resin case 51.

Next, functions of the above second embodiments are described.

The wiring harness 41 of the second embodiment can achieve effects similar to the effects (1) to (6), (9) and (10) of the first embodiment.

(11) The first and second divided cases 22, 23 include the intermediate locking portions 52e, 53e to be locked to each other between the two second shielded wires 13, 14. Thus, a space between the two second shielded wires 13, 14 can be effectively utilized by the intermediate locking portions 52e, 53e.

The above embodiments can be modified and carried out as follows. The above embodiments and the following modifications can be carried out in combination without technically contradicting each other.
Although the wiring harness 11, 41 is provided with the waterproof member 34 for collectively covering the resin case 21, the folded portions 12e, 13e and 14e, the shield coupling member 31 and the like in the above embodiments, there is no limitation to this and the waterproof member 34 may not be provided. Further, the waterproof member 34 may have another configuration having similar functions and, for example, may be a waterproof member including a tubular resin pipe and a rubber plug or a waterproof member constituted by a shrinkable tube or the like.

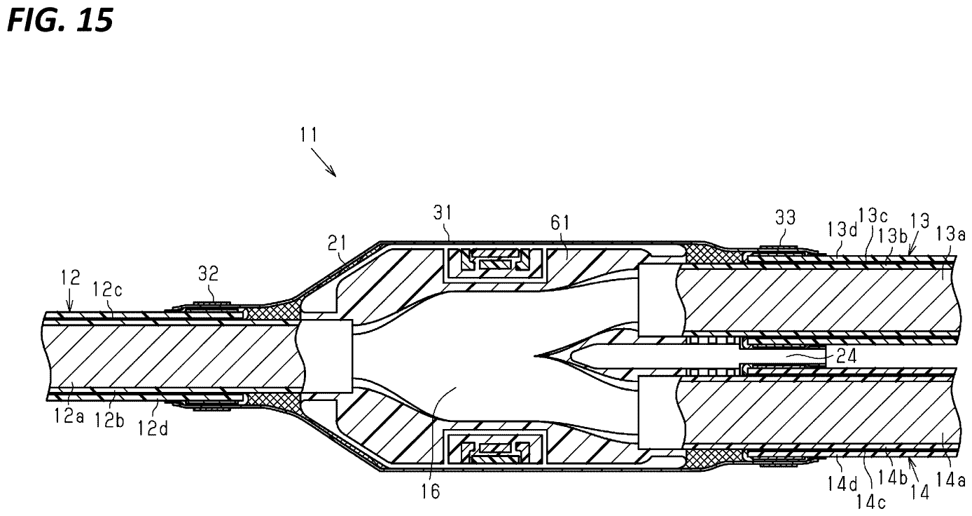

Further, for example, as shown in FIG. 15, the wiring harness 11 may not be provided with the waterproof member 34 and may be configured such that the shield coupling member 31, the crimp ring 32, the binding crimp ring 33 and the like are exposed while including a connecting portion waterproof member 61 for covering the connecting portion 16 in the resin case 21. The connecting portion waterproof member 61 is an electrically non-conductive mold resin. In particular, the connecting portion waterproof member 61 is a mold resin provided such that an electrically non-conductive resin material fills up a gap inside the resin case 21 while covering the outer periphery of the connecting portion 16.

Also in this way, the connecting portion 16 can be prevented from being wetted by the connecting portion waterproof member 61. Further, a size reduction can be, for example, achieved as compared to a configuration provided with the waterproof member 34 for collectively covering the shield coupling member 31 and the like. Further, a material reduction and a manufacturing cost reduction can be, for example, achieved according to the size reduction. Note that the wiring harness 11 provided with the waterproof member 34 and the wiring harness 11 provided with the connecting portion waterproof member 61 can be respectively provided as two types of products having different waterproof types, for example, according to users' demands.
Although the wiring harness 11, 41 is provided with the underlay rings 15 to be arranged between the outer insulation coatings 13d, 14d and the folded portions 13e, 14e in the above embodiments, there is no limitation to this and the underlay rings 15 may not be provided.

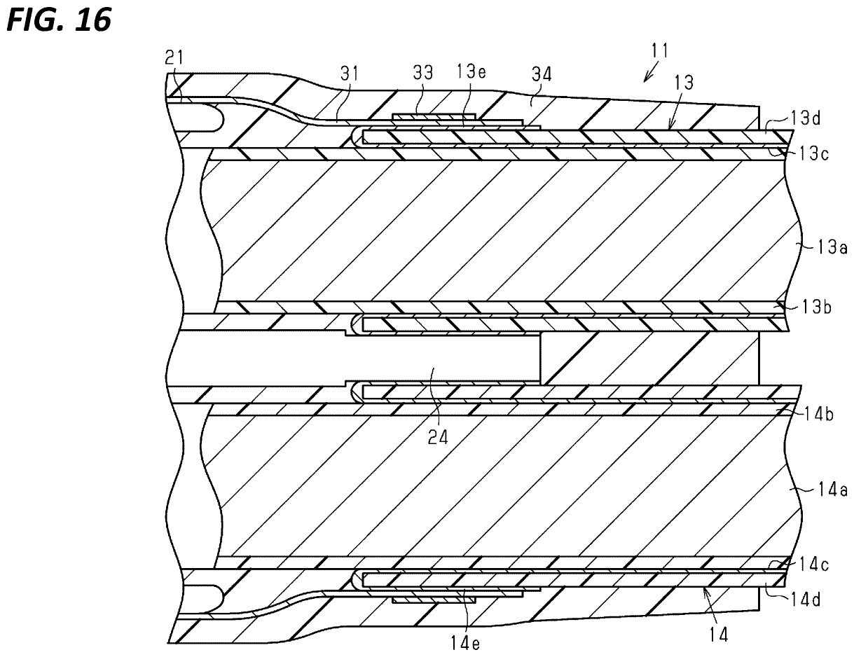

For example, as shown in FIG. 16, the folded portions 13e, 14e may be bound by the binding crimp ring 33 while being held in contact with the outer peripheral surfaces of the outer insulation coatings 13d, 14d. By doing so, the number of components can be reduced, for example, as compared to a configuration provided with the underlay rings 15 inside the folded portions 13e, 14e.
Although the spacer portion 24, 54 includes the arcuate portions 24a, 54a along the outer peripheries of the second shielded wires 13, 14 in the above embodiments, there is no limitation to this and the arcuate portions 24a, 54a may not be provided.
Although the second electromagnetic shield members 13c, 14c include the folded portions 13e, 14e arranged to cover the outer peripheries of the outer insulation coatings 13d, 14d in the above embodiments, there is no limitation to this and the folded portions 13e, 14e may not be provided. In this case, the second electromagnetic shield members 13c, 14c may be collectively bound with the shield coupling member 31 by the binding crimp ring 33 while being held in contact with the outer peripheries of the inner insulation coatings 13b, 14b.
Although the resin case 21, 51 includes the band restricting portions 24b, 54b engageable with the binding crimp ring 33 in the above embodiments, there is no limitation to this and the band restricting portions 24b, 54b may not be provided. Further, the positions, shapes and numbers of the band restricting portions 24b, 54b may be changed if a deviation of the binding crimp ring 33 along the longitudinal direction of the second shielded wires 13, 14 can be restricted.
Although the resin case 21, 51 includes the first divided case 22, 52 and the second divided case 23, 53 in the above embodiments, there is no limitation to this and a change may be, for example, made to a resin case in which a first dividing portion and a second dividing portion are integrally molded via a thin hinge portion. Further, the resin case 21, 51 may be composed of three or more divided cases.
Although the wiring harness 11 is provided with one first shielded wire 12 and two second shielded wires 13, 14 in the above embodiments, there is no limitation to this and the numbers of the first shielded wires 12 and the second shielded wires 13, 14 may be changed. Further, for example, the first shielded wire 12 extending in the direction opposite to the plurality of second shielded wires 13, 14 may not be provided while the plurality of second shielded wires 13, 14 extending in the same direction from the connecting portion 16, 43 are provided.
Although the first electromagnetic shield member 12c and the second electromagnetic shield members 13c, 14c are braided wires formed by braiding the strands into a tubular shape in the above embodiments, there is no limitation to this and the electromagnetic shield members 12c, 13c and 14c may be, for example, metal foils made of aluminum alloy or the like.
Although the shield coupling member 31 is a braided wire formed by braiding the strands into a tubular shape in the above embodiments, there is no limitation to this and the shield coupling member 31 may be, for example, a metal foil made of aluminum alloy. Further, the shield coupling member 31 may be configured to be arrangeable from the outside of the resin case 21, 51. For example, the shield coupling member 31 may be a braided wire formed by braiding the strands into a sheet-like shape or may be arranged to cover the outer periphery of the resin case 21, 51 by being wound on the resin case 21, 51 from the outside of the resin case 21, 51.
Although the binding band is the binding crimp ring 33 made of metal and formed into a tubular shape in the above embodiments, another binding band may be used if the second electromagnetic shield members 13c, 14c and the shield coupling member 31 can be collectively bound and connected. For example, a binding band made of resin and capable of collectively binding the plurality of second electromagnetic shield members 13c, 14c and the shield coupling member 31 may be used.

### Reference Examples

The resin case 21, 51 may be configured not to include the spacer portion 24, 54 for suppressing the deformation of the second shielded wires 13, 14 while including the band restricting portions 24b, 54b engageable with the binding crimp ring 33.

Technical ideas graspable from the above are described.

(A) A wiring harness is provided with a plurality of shielded wires each including a core wire and an electromagnetic shield member covering the outer periphery of the core wire, a connecting portion formed by connecting the core wires, a resin case for covering the outer periphery of the connecting portion, a shield coupling member to be connected to the plurality of electromagnetic shield members while covering the outer periphery of the resin case, and a binding band for collectively binding and connecting the respective electromagnetic shield members of the plurality of shielded wires and the shield coupling member while binding the plurality of shielded wires, and the resin case includes a band restricting portion engageable with the binding band to restrict a deviation of the binding band along a longitudinal direction of the shielded wires.

According to this configuration, the emission of electromagnetic waves from the periphery of the connecting portion is suppressed by covering the connecting portion by the shield coupling member. Further, since the plurality of electromagnetic shield members are collectively connected to the shield coupling member by the binding band, the number of components can be reduced, for example, as compared to a configuration in which the plurality of electromagnetic shield members are respectively connected to the shield coupling member by a plurality of binding bands or the like. Further, since a deviation of the binding band along the longitudinal direction of the shielded wires is restricted by the band restricting portion, a connected state of the plurality of electromagnetic shield members and the shield coupling member can be stably maintained. Further, since the band restricting portion is provided in the resin case, the number of components can be reduced, for example, as compared to the case where the band restricting portion and the resin case are separately provided.

For example, a configuration in which the electromagnetic shield members were merely directly connected outside the connecting portion had a problem of being difficult to satisfactorily connect the electromagnetic shield members while satisfactorily covering the entire periphery of the connecting portion. In contrast, the connected state of the electromagnetic shield members can be stably maintained by a simple configuration and the emission of electromagnetic waves from the periphery of the connecting portion can be satisfactorily suppressed.

The wiring harnesses of the shown embodiments may be wiring harnesses for vehicle as in Patent Document 1.

As shown in FIGS. 4 and 5, the first divided spacer portion 22f of the spacer portion 24 may be formed to project, for example, linearly in the longitudinal direction of the second shielded wires 13, 14 from between the semicircular openings 22b, 22 of the first divided case 22, in which the inner insulation coatings 13b, 14b of the second shielded wires 13, 14 are located. The second divided spacer portion 23f of the spacer portion 24 may be formed to project, for example, linearly in the longitudinal direction of the second shielded wires 13, 14 from between the semicircular openings 23b, 23c of the second divided case 23, in which the inner insulation coatings 13b, 14b of the second shielded wires 13, 14 are located. The same also applies to the spacer portion 54.

As shown in FIGS. 4 to 7, the spacer portion 24 may include the pair of arcuate portions 24 formed on the both surfaces to be sandwiched by the second shielded wires 13, 14. The first and second divided spacer portions 22f, 23f of the spacer portion 24 may be inserted between the second shielded wires 13, 14 from a lateral side of the second shielded wires 13, 14. With the first and second divided spacer portions 22f, 23f inserted between the second shielded wires 13, 14, the pair of arcuate portions 24a may be formed by the first and second divided spacer portions 22f, 23f. The same also applies to the spacer portion 54.

The pair of arcuate portions 24a of the spacer portion 24 may have curved surfaces to be respectively fit to the outermost surfaces (folded portions 13e, 14e) of the second electromagnetic shield members 13c, 14c of the two second shielded wires 13, 14. In the shown example, the spacer portion 24 can include a plurality of plate-like ribs separated from each other at fixed intervals along the longitudinal direction of the second shielded wires 13, 14 and each of the plurality of plate-like ribs can have a curved surface to be fit to the outermost surface (folded portion 13e or 14e) of the second electromagnetic shield member 13c or 14c of the second shielded wire 13 or 14. The spacer portion 24 or the pair of arcuate portions 24a of the spacer portion 24 may be referred to as electromagnetic shield receiving surface(s) or electromagnetic shield support surface(s). The same also applies to the spacer portion 54.

### List of Reference Numerals

11 wiring harness
12 first shielded wire (shielded wire)
12a first core wire (core wire)
12b inner insulation coating
12c first electromagnetic shield member (electromagnetic shield member)
12d outer insulation coating
12e folded portion
13 second shielded wire (shielded wire)
13a second core wire (core wire)
13b inner insulation coating
13c second electromagnetic shield member (electromagnetic shield member)
13d outer insulation coating
13e folded portion
14 second shielded wire (shielded wire)
14a second core wire (core wire)
14b inner insulation coating
14c second electromagnetic shield member (electromagnetic shield member)
14d outer insulation coating
14e folded portion
15 underlay ring
16 connecting portion
21 resin case
22 first divided case
22a semicircular opening
22b semicircular opening
22c semicircular opening
22d locking portion
22e locking portion
22f first divided spacer portion
23 second divided case
23a semicircular opening
23b semicircular opening
23c semicircular opening
23d locking portion
23e locking portion
23f second divided spacer portion
24 spacer portion
24a arcuate portion
24b band restricting portion
31 shield coupling member
32 crimp ring
33 binding crimp ring (binding band)
33a semicircular portion
33b coupling portion
34 waterproof member
41 wiring harness
42 connection terminal
43 connecting portion
51 resin case
52 first divided case
52a semicircular opening
52b semicircular opening
52c semicircular opening
52d through hole
52e intermediate locking portion
52f positioning recess
52g first divided spacer portion
53 second divided case
53a semicircular opening
53b semicircular opening
53c semicircular opening
53d through hole
53e intermediate locking portion
53f positioning protrusion
53g second divided spacer portion
54 spacer portion
54a arcuate portion
54b band restricting portion
61 connecting portion waterproof member

1. A wiring harness, comprising:
a plurality of shielded wires each including a core wire and an electromagnetic shield member covering an outer periphery of the core wire;
a connecting portion formed by connecting the core wires to each other;
a resin case for covering an outer periphery of the connecting portion;
a shield coupling member to be connected to a plurality of the electromagnetic shield members while covering an outer periphery of the resin case; and
a binding band for collectively binding and connecting the respective electromagnetic shield members of the plurality of shielded wires and the shield coupling member while binding the plurality of shielded wires,
the resin case including a spacer portion for suppressing deformation of the plurality of shielded wires by being interposed between the plurality of shielded wires inside the binding band.

212. The wiring harness of claim 1, wherein the spacer portion includes arcuate portions along outer peripheries of the shielded wires.

3. The wiring harness of claim 1, wherein:
the shielded wire includes an outer insulation coating covering an outer periphery of the electromagnetic shield member,
the electromagnetic shield member includes a folded portion folded from inside to outside of the outer insulation coating and arranged to cover an outer periphery of the outer insulation coating, and
the binding band collectively binds the folded portions and the shield coupling member.

4. The wiring harness of claim 3, comprising an underlay ring to be arranged between the outer insulation coating and the folded portion.

5. The wiring harness of claim 3, wherein the folded portions are bound by the binding band while being held in contact with outer peripheral surfaces of the outer insulation coatings.

6. The wiring harness of claim 1, wherein the resin case includes a band restricting portion engageable with the binding band to restrict a deviation of the binding band along a longitudinal direction of the shielded wires.

7. The wiring harness of claim 1, wherein the resin case includes a first divided case and a second divided case to be assembled to sandwich the connecting portion.

8. The wiring harness of claim 7, wherein the first and second divided cases have the same shape.

919. The wiring harness of claim 7, wherein the first and second divided cases include locking portions to be locked to each other on both sides in a width direction, the width direction being an arrangement direction of the plurality of shielded wires to be bound by the binding band.

10. The wiring harness of claim 7, wherein the first and second divided cases include intermediate locking portions to be locked to each other between the plurality of shielded wires to be bound by the binding band.

11. The wiring harness of claim 1, wherein:
the plurality of shielded wires include a first shielded wire and a second shielded wire extending in directions opposite to each other with the connecting portion as a base point, and
at least a plurality of the first shielded wires or a plurality of the second shielded wires are provided and bound by the binding band.

12. The wiring harness of claim 1, comprising a waterproof member for collectively covering the resin case, the electromagnetic shield members, the shield coupling member and the binding band.

13. The wiring harness of claim 1, comprising a connecting portion waterproof member for covering the connecting portion in the resin case, wherein:
the shield coupling member and the binding band are exposed.
